(19) United States
(12) Patent Application Publication
(10) Pub. No.: US 2008/0290942 A1
(43) Pub. Date: Nov. 27, 2008

(54) DIFFERENTIAL AMPLIFIER

(75) Inventor: Takahiko Shimizu, Ooizumimado (JP)

Correspondence Address: MARTINE PENILLA & GENCARELLA, LLP, 710 LAKEWAY DRIVE, SUITE 200, SUNNYVALE, CA, 94085, US

(73) Assignee: ADVANTEST CORPORATION, Tokyo (JP)

(21) Appl. No.: 12/122,644

(22) Filed: May 16, 2008

(30) Foreign Application Priority Data
May 17, 2007 (JP) JP2007-132092

(51) Int. Cl. H03F 3/45

(52) U.S. Cl. 330/253

(57) ABSTRACT

A cascode current mirror circuit is connected as an active load to the input differential pair. A tail current source supplies a tail current to the input differential pair. A constant current source is connected in parallel with the input differential pair, and supplies a constant current to the tail current source. The constant current supplied by the constant current source is set to a value at which a transistor is not cut off.

### CLAIM OF PRIORITY

This Application claims foreign priority from Japanese Application No. 2007-132092, filed on May 17, 2007.

### BACKGROUND OF INVENTION

1. Field of the Invention

The present invention relates to a differential amplifier.

2. Description of the Related Art

Differential amplifiers, and operational amplifiers or comparators that make use of differential amplifiers (referred to generically below simply as differential amplifiers) are widely used in all types of applications as basic circuits forming electronic circuits. In general a differential amplifier includes an input differential pair, a current mirror circuit or a resistor pair, which acts as a load on the input differential pair, and a tail current source which supplies a tail current to the input differential pair.

In order to hold constant a drain-source voltage of a transistor of the input differential pair of the differential amplifier (or a collector-emitter voltage; below, no particular distinction is made between a field-effect transistor and a bipolar transistor, and a drain-source voltage is referred to), or to improve gain, there are cases in which a cascode current mirror circuit is used as the current mirror circuit (for example, refer to Patent Document 1).

FIG. 3 is a circuit diagram of an amplifier provided with a cascode current mirror circuit as an active load. The amplifier 200 includes an input differential pair 10, a cascode current mirror circuit 20, and a tail current source 30. The input differential pair 10 includes N-channel MOSFETs (Metal Oxide Semiconductor Field Effect Transistor) M1 and M2, and input signals Vin− and Vin+ are inputted to respective gates thereof. The tail current source 30 includes a constant current source 32 and transistors M7 and M8. The constant current source 32 generates a reference current Iref, a current mirror circuit including transistors M8 and M7 multiplies by a numerical constant the reference current Iref, to supply a tail current It to the input differential pair 10. The cascode current mirror circuit 20 is connected as an active load of the input differential pair 10, and includes transistors M3 to M6 which are P-channel MOSFETs. A bias voltage Vc is applied to gates of the transistors M3 and M4. By a current mirror circuit being a 2-stage cascode type provided with transistors M3 and M4, a small signal operating point of drain-source voltage of transistors M1 and M2 is constant, and it is possible to obtain a stable gain.

Patent Document 1: Japanese Patent Application, Laid Open No. 2003-101358

Operation when a large amplitude signal is inputted to the amplifier 200 of FIG. 3 is examined. If the input signal Vin+ fully swings in a negative direction, the transistors M2, M7, and M1 are cut off, and a large voltage is applied between drain and source of the transistors M1 and M2 of the input differential pair 10. As a result, the transistors M1 and M2 of the input differential pair 10 must be configured using high voltage elements, and problems have arisen such as increase in element area, decrease in bandwidth, increase in cost, and the like.

### SUMMARY OF THE INVENTION

The present invention has been made in consideration of these problems and a general purpose thereof is to provide a differential amplifier which is configurable by a low voltage element.

An embodiment of the invention relates to a differential amplifier. The differential amplifier is provided with an input differential pair, a cascode current mirror circuit having at least 2 stages connected as a load on the input differential pair, a tail current source which supplies a tail current to the input differential pair, and a constant current source, which is connected in parallel with the input differential pair, and which supplies a constant current to the tail current source.

In the present invention, “supplying a current” includes both cases in which a current is flowed in a certain path (push), and cases in which current is drawn from a certain path (pull).

According to this embodiment, even in cases in which a large amplitude input signal is inputted to the input differential pair, since a constant current flows to the tail current source, it is possible to prevent a transistor from being cut off. As a result, it is possible to restrain increase in voltage of both ends of the input differential pair (drain-source voltage or collector-emitter voltage), and it is possible to use low voltage elements as the input differential pair.

The tail current source may include a tail transistor arranged between a first fixed voltage terminal and a common connection point of the input differential pair. The constant current supplied by the constant current source may be set to a value at which the tail transistor is not cut off. The constant current supplied by the constant current source may be in range of from 1/20 to ⅕ of the tail current.

The tail current source may include a tail transistor arranged between a first fixed voltage terminal and a common connection point of the input differential pair. The constant current source may include a first transistor connected to a tail transistor in a current mirror configuration, a second transistor connected between the first transistor and a second fixed voltage terminal, a third transistor connected to the second transistor in a current mirror configuration, a level shift circuit arranged between a terminal on a side opposite to the second fixed voltage terminal of the third transistor and a common connection point of the input differential pair, and may supply, as the constant current, a current flowing in a path including the third transistor and the level shift circuit. A potential of a connection point of the third transistor and the level shift circuit may be supplied as a bias voltage of the cascode current mirror circuit. In such cases, it is possible to stabilize the bias voltage of the cascode current mirror circuit.

The level shift may include a level shift transistor in which a control terminal and a terminal connected to the third transistor are commonly connected. The level shift transistor may be of a similar type to the transistors that make up the input differential pair. The “control terminal” indicates a gate in an FET and a base in a bipolar transistor.

The level shift circuit may include a diode.

The differential amplifier in a certain embodiment may be monolithically integrated on one semiconductor substrate and may be configured using a low voltage process. As described above, since voltage applied to the input differential pair of the differential amplifier can be decreased, usage of the low voltage process is possible, and as a result, it is possible to realize increasing speed and lowering of cost of a circuit with decreasing area and increasing bandwidth.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram showing a configuration of a differential amplifier according to an embodiment;

FIG. 2 is a circuit diagram showing a specific configuration example of the differential amplifier of FIG. 1; and

FIG. 3 is a circuit diagram of an amplifier provided with a cascode current mirror circuit as an active load.

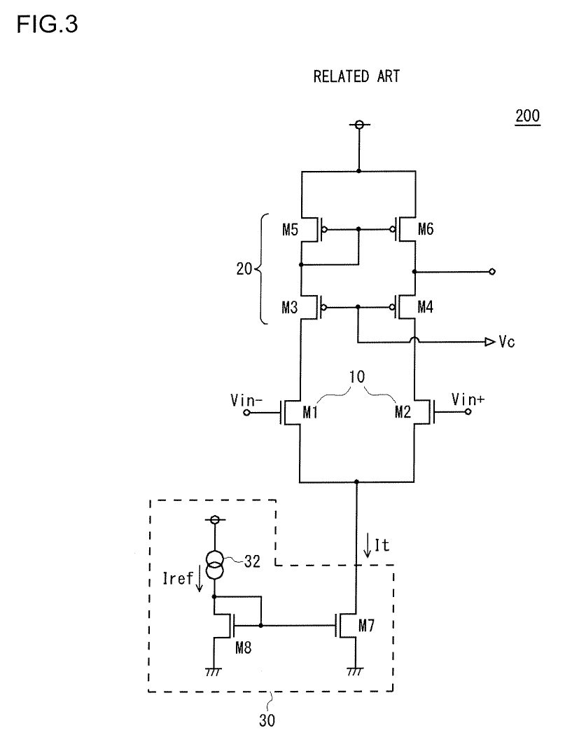

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

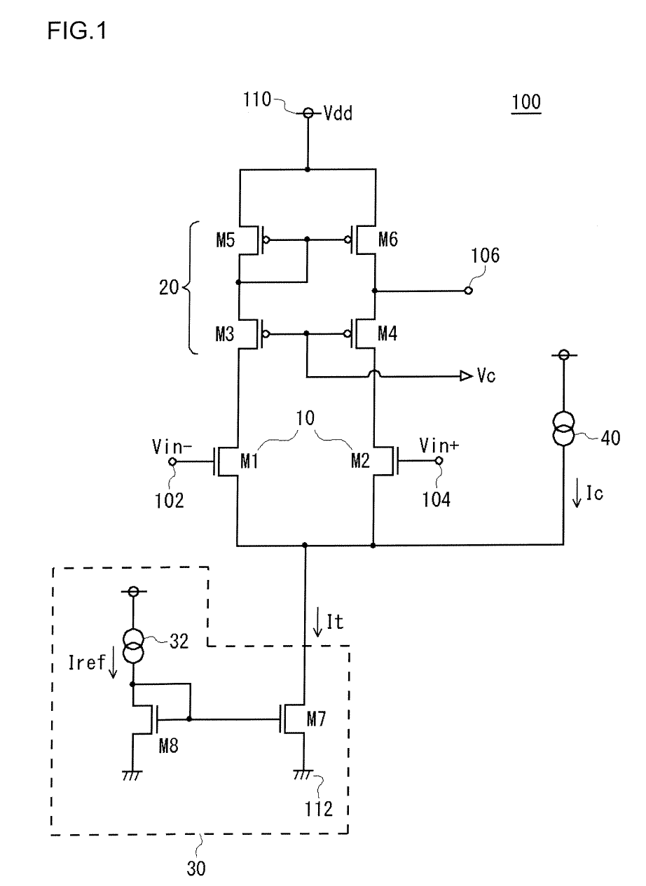

FIG. 1 is a circuit diagram showing a configuration of a differential amplifier 100 according to an embodiment. In the differential amplifier 100, signals Vin− and Vin+ inputted to an inverting input terminal 102 and a noninverting input terminal 104 are differentially amplified to be outputted from an output terminal 106.

The amplifier 100 is provided with an input differential pair 10, a cascode current mirror circuit 20, a tail current source 30, and a constant current source 40.

The input differential pair includes a first transistor M1 whose gate is connected to the inverting input terminal 102, and a second transistor M2 whose gate is connected to the noninverting input terminal 104. Sources of the first transistor M1 and the second transistor M2 are commonly connected. The first transistor M1 and the second transistor M2 are N-channel MOSFETs. Although not shown in the drawings, a back gate of each transistor is connected to a source.

The cascode current mirror circuit 20 is connected as an active load on a drain side of the input differential pair 10. In the cascode current mirror circuit 20, a current mirror circuit of at least two stages is built longitudinally and connected. The present embodiment shows a two stage example. The cascode current mirror circuit 20 includes a third transistor M3 to a sixth transistor M6. The third transistor M3, the fourth transistor M4, the fifth transistor M5 and the sixth transistor M6 are P-channel MOSFETs.

The fifth transistor M5 and the sixth transistor M6 are connected in a current mirror configuration. That is, gate and source thereof are commonly connected, and the common source is connected to a second fixed voltage terminal (power supply terminal 110). Source and drain of the fifth transistor M5 are also connected.

The third transistor M3 and the fourth transistor M4 are cascode connected with respect to the first transistor M1 and the second transistor M2. That is, gates of the third transistor M3 and the fourth transistor are commonly connected and a bias voltage Vc is applied. Drains of the third transistor M3 and the fourth transistor M4 are respectively connected to drains of the first transistor M1 and the second transistor M2. Sources of the third transistor M3 and the fourth transistor M4 are respectively connected to drains of the fifth transistor M5 and the sixth transistor M6.

The tail current source 30 supplies a tail current It to the input differential pair 10. The tail current source 30 includes a constant current source 32, a seventh transistor (tail transistor) M7, and an eighth transistor M8. The constant current source 32 generates a reference current Iref. The eighth transistor M8 is arranged on a path of the reference current Iref. The seventh transistor M7 is an N-channel MOSFET of a similar type to the eighth transistor M8, and is connected in a current mirror configuration to the eighth transistor M8. That is, the seventh transistor M7 is arranged between a first fixed voltage terminal (ground terminal 112) and a common connection point (source) of the first transistor M1 and the second transistor M2. Current flowing in the seventh transistor M7 is supplied to the input differential pair 10 as the tail current It.

The constant current source 40 is connected in parallel with the input differential pair 10, and supplies a constant current Ic to the tail current source 30. That is, in a steady state, the following relationship holds between the tail current It, a current Id (not shown in the drawings) flowing in the input differential pair 10, and the constant current Ic:

It=Ic+Id

In other words, the constant current source 40 is provided in order to supply part of the tail current in a separate path to the input differential pair 10.

The constant current Ic supplied by the constant current source 40 is preferably set to a value at which the seventh transistor (tail transistor) M7 is not cut off, in other words, to a value at which the seventh transistor M7 operates in a linear range (triode region). The value of the constant current Ic may be set according to size of the seventh transistor M7. For example, the constant current Ic is preferably in a range from 1/20 to ⅕ of the tail current It. If this range is set, it is possible to keep a preferable balance in tradeoff between an object of making the seventh transistor M7 operate in a linear region and of increasing circuit current.

Operation of the differential amplifier 100 configured as above will be described. When a large amplitude input signal Vin+ in a negative direction is inputted to the noninverting input terminal 104, the second transistor M2 is cut off. At this time, since at least the constant current Ic is flowing in the seventh transistor M7, the seventh transistor M7 is not cut off and operates in a linear region. That is, drain-source voltage Vds of the seventh transistor M7 does not drop to, or below, a constant value determined by the constant current Ic, and source voltage of the first transistor M1 and the second transistor M2 is maintained, to some extent, at a high value.

On the other hand, drain voltage of the first transistor M1 and the second transistor M2 can be controlled by adjusting the bias voltage Vc applied to gates of the third transistor M3 and the fourth transistor M4. Therefore, in the present embodiment, it is possible to restrain the drain-source voltage Vds of the first transistor M1 and the second transistor M2 from becoming large. Cases in which a large amplitude signal in inputted to the inverting input terminal 102 are similar.

According to the differential amplifier 100 according to the present embodiment, even if a large amplitude input signal is inputted to the first transistor M1 and the second transistor M2, since it is possible to curtail the drain-source voltage of the first transistor M1 and the second transistor M2, a configuration using low voltage elements is possible. In general, with low voltage elements, the number of masks used in a semiconductor production process is small in comparison to high voltage elements, and since circuit area is small, it is possible to realize cost lowering and miniaturization. Furthermore, since device performance is higher with low voltage elements, in applications in which high speed operations are needed, the differential amplifier 100 according to the present embodiment is advantageous.

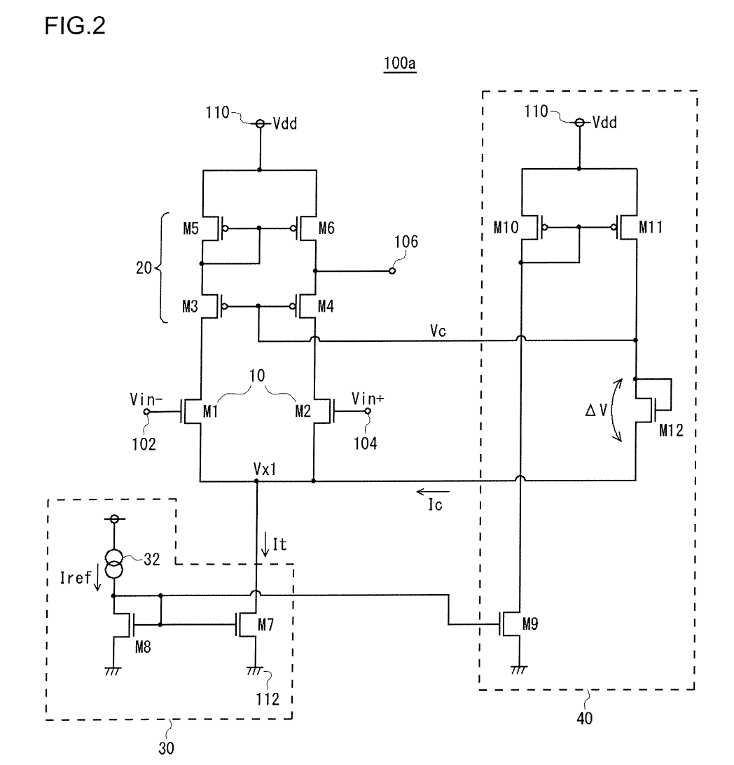

FIG. 2 is a circuit diagram showing a specific configuration example of the differential amplifier of FIG. 1. In a differential amplifier 100a of FIG. 2, the constant current source 40 includes a ninth transistor M9 to a twelfth transistor M12.

The tenth transistor M10 and the eleventh transistor M11 are P-channel MOSFETs, and the ninth transistor M9 and the twelfth transistor M12 are N-channel MOSFETs. If correspondences are made with the claims, the ninth transistor M9 to the eleventh transistor M11 of FIG. 2 correspond to the first transistor to the third transistor of the claims, and the twelfth transistor M12 corresponds to the level shift circuit of the claims.

The ninth transistor M9 is connected in a current mirror configuration to the seventh transistor (tail transistor) M7 and the eighth transistor M8. The tenth transistor M10 is connected between a drain of the ninth transistor M9 and the power supply terminal 110 (second fixed voltage terminal). The eleventh transistor M11 is connected in a current mirror configuration to the input differential pair 10. The twelfth transistor M12, with gate and drain connected, functions as a level shift circuit. The twelfth transistor M12 is arranged between a terminal (source) on an opposite side to the power supply terminal 110 of the eleventh transistor M11 and a common connection point of the first transistor M1 and the second transistor M2 of the input differential pair 10. The constant current source 40 supplies a current flowing in a path including the eleventh transistor M11 and the twelfth transistor M12, as the constant current Ic.

Furthermore, potential of a connection point (drain) of the twelfth transistor M12 and the eleventh transistor M11 is outputted as the bias voltage Vc of the cascode current mirror circuit 20.

As shown in FIG. 2, the level shift circuit is preferably of a similar type to transistors (M1, M2) that configure the input differential pair 10, that is, has an N-channel configuration.

Circuit operation of FIG. 2 will be described. A current proportional to the reference current Iref flows in the ninth transistor M9. Current flowing in the ninth transistor M9 is multiplied by a numerical constant by the current mirror circuit (M10, M11), and the constant current Ic is generated. Here, when the constant current Ic flows in the twelfth transistor M12 that is self-biased, a constant potential difference is generated between drain and source of the twelfth transistor M12. If this potential difference is written as ΔV, the bias current Vc supplied to the cascode current mirror circuit 20 is represented as Vc=Vx1+ΔV. Here Vx1 is potential of a common connection point of the first transistor M1 and the second transistor M2. In order to adjust the potential difference ΔV, the twelfth transistor M12 may be connected in multiple stages in series. By increasing the stages of the twelfth transistor M12, it is possible to obtain a large potential difference when the constant current Ic is small.

If the input signal Vin− is inputted with a large amplitude in a negative direction, the second transistor M2 is cut off, current flowing in the seventh transistor M7 decreases to approximately the constant current Ic, and voltage Vx1 decreases. At this time, since the bias voltage Vc decreases together with the voltage Vx1, the extent to which the third transistor M3 and the fourth transistor M4 are ON is adjusted. As a result, according to the circuit of FIG. 2, it is possible to prevent cut off of the seventh transistor M7 by the constant current Ic, and also it is possible to provide a suitable bias voltage Vc in accordance with circuit operation state.

The embodiment above is merely an example and various modified technologies can be envisaged in configurations and process steps thereof. An example is described below.

In the circuits of FIG. 1 or FIG. 2, MOSFETs may be substituted by bipolar transistors. That is, N-channel MOSFETs may be configured by NPN bipolar transistors, and P-channel MOSFETs may be configured by PNP bipolar transistors. In such cases, the twelfth transistor M12 may be configured as a diode. Moreover, a resistor may be used as the level shift circuit. The level shift circuit may be configured by arbitrarily combining the twelfth transistor M12, a diode, and a resistor.

The differential amplifier 100 according to the present embodiment can also be applied to a P-channel input circuit. In such cases, an N-channel configuration may be substituted for a P-channel configuration, and the power supply terminal 110 and the ground terminal 112 may be inversed in a top-to-bottom manner.

Furthermore, a current mirror circuit may be used as the level shift circuit. That is, a transistor M13 may be arranged between the ninth transistor M9 and the tenth transistor M10, and the twelfth transistor M12 and the transistor M13 may be connected in a current mirror configuration with a common gate.

While the preferred embodiments of the present invention have been described using specific terms, such description is for illustrative purposes only, and it is to be understood that changes and variations may be made without departing from the spirit or scope of the appended claims.

1. A differential amplifier comprising:
an input differential pair;
a cascode current mirror circuit having at least 2 stages connected as a load on the input differential pair;
a tail current source which supplies a tail current to the input differential pair; and
a constant current source which is connected in parallel with the input differential pair, and supplies a constant current to the tail current source.

2. The differential amplifier according to claim 1, wherein a constant current supplied by the constant current source is in a range of from 1/20 to ⅕ of the tail current.

3. The differential amplifier according to claim 1, wherein the tail current source comprises a tail transistor arranged between a common connection point of the input differential pair and a first fixed voltage terminal; and
the constant current source comprises a first transistor connected to the tail transistor in a current mirror configuration;
a second transistor connected between the first transistor and a second fixed voltage terminal;
a third transistor connected to the second transistor in a current mirror configuration; and
a level shift circuit arranged between a terminal on a side opposite to the second fixed voltage terminal of the third transistor and a common connection point of the input differential pair;
and supplies, as the constant current, a current flowing in a path including the third transistor and the level shift circuit;
and a potential of a connection point of the third transistor and the level shift circuit is supplied as a bias voltage of the cascode current mirror circuit.

4. The differential amplifier according to claim 3, wherein the level shift circuit comprises:
a level shift transistor in which a control terminal and a terminal connected to the third transistor are commonly connected, the level shift transistor being of a similar type to transistors of which the input differential pair is configured.

5. The differential amplifier according to claim 3, wherein the level shift circuit comprises a diode.

6. The differential amplifier according to claims 1, wherein the differential amplifier is integrated on one semiconductor substrate and is configured using a low voltage process.
